(19) United States
(12) Patent Application Publication
(10) Pub. No.: US 2026/0111290 A1
(43) Pub. Date: Apr. 23, 2026

(54) SYSTEM FOR AND METHOD OF HARNESSING HEAT GENERATED FROM RUNNING AT LEAST ONE VIRTUAL OPERATIVE SYSTEM INSTANCE

(71) Applicant: Green Data Center Technologies AS, Hafrsfjord (NO)

(72) Inventors: Richard Rettedal, SANDNES (NO); Bjørn Knudsen, HAFRSFJORD (NO); Christopher Birkeland, STAVANGER (NO); Matt Chauncy-Lie, STAVANGER (NO)

(73) Assignee: Green Data Center Technologies AS, Hafrsfjord (NO)

(21) Appl. No.: 19/154,590

(22) PCT Filed: Feb. 12, 2024
(86) PCT No.: PCT/NO2024/050031

§ 371 Date: Aug. 7, 2025

(30) Foreign Application Priority Data
Feb. 10, 2023 (NO) 20230136

(51) Int. Cl. G06F 9/50; G06F 30/20

(52) U.S. Cl. CPC G06F 9/5094; G06F 30/20

(57) ABSTRACT

Systems for and methods of harnessing heat generated from running virtual operative system instances. A system may include: host computers for running the virtual operative system instances, the host computers being networked; and a subsystem for harnessing heat generated by the host computers. One or more of the host computers may be configured to operate as a controller. Alternatively, a separate controller computer may be provided. The controller or controller computer is configured with the steps of: for each instance, estimating a heat rate that will result from running the instance as a guest of a host computer; calculating an arrangement of the instances over the host computers so that a heat rate achieved by the host computers is maximized; and controlling the host computers to run the instances as defined in the calculated arrangement.

### CROSS-REFERENCE TO RELATED APPLICATIONS

This application is the U.S. national stage application of International Application No. PCT/NO2024/050031, filed Feb. 12, 2024, which international application was published on Aug. 15, 2024, as WO 2024/167418 in the English language. The International Application claims priority to Norwegian Patent Application No. 20230136, filed on Feb. 10, 2023. The international application and Norwegian application are both incorporated herein by reference, in their entirety.

### FIELD

The present invention relates to systems for harnessing heat generated from running at least one virtual operative system instance. The present invention also relates to methods of harnessing heat generated from running at least one virtual operative system instance.

### BACKGROUND

Nowadays, sustainability is becoming an increasing priority in the data center industry. For example, some known developments aim to harness heat (aka. to harvest heat) generated by running computers in a data center and then have the harnessed heat be supplied to an external facility. The harnessed heat can be used for heating buildings (e.g. an apartment building, a public swimming pool facility) or food production processes (e.g. greenhouses) that require heat.

There are various known solutions for harnessing heat from computers used in a data center. For example, a known heat harnessing system is based on a direct contact evaporative cooling system (e.g. ZutaCore HyperCool^{2™}), in which at least one heat generating chip (e.g. a Central Processing Unit chip) is equipped with a device for transferring heat from the chip to a coolant (e.g. 3M™ Novec™ 7000 Engineered Fluid). The heat ensuing from the heat transfer is then transmitted to and used at the external facility. Other heat harnessing systems are also known.

In this context, it observed that it can be challenging to orchestrate instances of virtual operative systems as guests of at least two host computers, when the at least two host computers are being used as a source of heat for a heat harnessing system.

Running instances of virtual operative systems as guests of a host computer allows the hardware resources of the host computer to be shared with the instances. Known approaches for running an instance of a virtual operative system include: a hypervisor software (e. g KVM), which runs at least one virtual machine instance on the host computer; and a container engine software (e.g. Docker), which runs at least one container instance on the host computer. Due to each instance requiring computational resources in a way that varies over time, the overall requirements for hardware resources of the host computers change over time.

In known art, “orchestration” refers to methods of monitoring and managing in which of the at least two host computers is each instance of a virtual operative system being run. Several factors may be taken into account when orchestrating (virtual machine or container) instances. Typically, known orchestration methods aim to cool down hardware as efficiently as possible while achieving an even and low computing load on all host computers. Known orchestration methods may aim to even out server load in order to avoid the risk of overheating the hardware, which could lead to damage and/or failure. The known orchestration methods typically achieve low rates of the harnessed heat relative to the consumption of hardware resources by the instances in the at least two host computers.

### SUMMARY

The invention will now be disclosed and has for its object to remedy or to reduce at least one of the drawbacks of the prior art, or at least provide a useful alternative to prior art. The object is achieved through features, which are specified in the description below and in the claims that follow. The invention is defined by the independent claims. The dependent claims define advantageous embodiments of the invention.

According to a first aspect of the invention, there is provided a system for harnessing heat generated from running at least one virtual operative system instance. The system comprises:
at least two host computers for running the at least one virtual operative system instance, the at least two host computers being networked; and
a subsystem for harnessing heat generated by the at least two host computers. One or more of the at least two host computers is configured to operate as a controller of the at least two host computers. The controller is configured to carry out the steps of:
for each virtual operative system instance, estimating a heat rate that will result from running the instance as a guest of a host computer;
calculating an arrangement of the at least one virtual operative system instance over the at least two host computers so that a heat rate achieved by the at least two host computers is maximized; and
controlling the at least two host computers to run the at least one virtual operative system instance as defined in the calculated arrangement.

Thus, the system achieves a maximization of the heat rate generated by the at least two host computers in use relative to the number of virtual operative system instances being run. Thus, the residual heat levels per host computer are increased, which makes the at least two host computers more useful for the purpose of heat harnessing. Also, the system is advantageous in that the amount of host machines needed for the same workloads (caused by the virtual operative system instances) is reduced.

Optionally, for each host computer, the controller is configured with a target minimum heat rate to be achieved by the host computer, and the step of calculating an arrangement comprises the step of calculating an arrangement of the at least one virtual operative system instance over the at least two host computers so that an amount of host computers achieving the respective target minimum heat rate is maximized. Thus, the system can be configured to aim for a target minimum heat rate to be achieved by a host computer when the host computer is controlled to run a virtual operative system instance. This embodiment is advantageous, for example, when the subsystem for harnessing heat generated by the at least two host computers has an improved harnessing efficiency that depends on the host computer generating heat above a defined amount (e.g. an amount of heat sufficient to cause the evaporation of a coolant fluid). Thus, when calculating an arrangement of the at least one virtual operative system instance over the at least two host computers, the system can optimize the calculation based on the heat harnessing capabilities of the subsystem. Therefore, significant amounts of heat may be harnessed over time, the harnessed heat being usable in an external facility.

Optionally, the step of estimating a heat rate comprises estimating the heat rate based on any of:
previous data about a heat rate that resulted from running the virtual operative system instance as a guest of a host computer;
real-time data about a heat rate that is resulting from running the virtual operative system instance as a guest of a host computer;
data generated by a mathematical model of a heat rate that results from running the virtual operative system instance as a guest of a host computer; and/or
data generated by a computer implemented simulation of a heat rate that results from running the virtual operative system instance as a guest of a host computer.

Optionally, the step of controlling the at least two host computers to run the at least one virtual operative system instance comprises the step of migrating a virtual operative system instance from one host computer to a different host computer.

Optionally, the controller is further configured to carry out any of the steps of:
shutting down a host computer that has not been controlled to run at least one virtual operative system instance; or
controlling a host computer that has not been controlled to run at least one virtual operative system instance so that the host computer runs in a mode for saving energy. Thus, the number of resources running idle per host computer is minimized.

Optionally, the at least one virtual operative system instance comprises any of: a virtual machine instance; and/or a container instance.

According to a second aspect of the invention, there is provided a method of harnessing heat generated from running at least one virtual operative system instance. The method comprises the steps of:
providing at least two host computers for running the at least one virtual operative system instance, the at least two host computers being networked;
providing a subsystem for harnessing heat generated by the at least two host computers;
configuring one or more of the at least two host computers to operate as a controller of the at least two host computers;
for each virtual operative system instance, estimating a heat rate that will result from running the instance as a guest of a host computer;
calculating an arrangement of the at least one virtual operative system instance over the at least two host computers so that a heat rate achieved by the at least two host computers is maximized; and
controlling the at least two host computers to run the at least one virtual operative system instance as defined in the calculated arrangement.

Optionally, the method comprises the step of:
for each host computer, configuring the controller with a target minimum heat rate to be achieved by the host computer, and
   wherein the step of calculating an arrangement comprises the step of:
calculating an arrangement of the at least one virtual operative system instance over the at least two host computers so that an amount of host computers achieving the respective target minimum heat rate is maximized.

Optionally, the step of estimating a heat rate comprises estimating the heat rate based on any of:
previous data about a heat rate that resulted from running the virtual operative system instance as a guest of the host computer;
real-time data about a heat rate that is resulting from running the virtual operative system instance as a guest of a host computer;
data generated by a mathematical model of a heat rate that results from running the virtual operative system instance as a guest of a host computer; and/or
data generated by a computer implemented simulation of a heat rate that results from running the virtual operative system instance as a guest of a host computer.

Optionally, the step of controlling the at least two host computers to run the at least one virtual operative system instance comprises the step of migrating a virtual operative system instance from one host computer to a different host computer.

Optionally, the controller is further configured to carry out any of the steps of:
shutting down a host computer that has not been controlled to run at least one virtual operative system instance; or
controlling a host computer that has not been controlled to run at least one virtual operative system instance so that the host computer runs in a mode for saving energy.

Optionally, the at least one virtual operative system instance comprises any of: a virtual machine instance; and/or a container instance.

According to a third aspect of the invention, there is provided a system for harnessing heat generated from running at least one virtual operative system instance, the system comprising:
at least two host computers for running the at least one virtual operative system instance, the at least two host computers being networked;
a subsystem for harnessing heat generated by the at least two host computers; and
a controller computer for controlling the at least two host computers.

The controller computer is configured to carry out the steps of:
for each virtual operative system instance, estimating a heat rate that will result from running the instance as a guest of a host computer;
calculating an arrangement of the at least one virtual operative system instance over the at least two host computers so that a heat rate achieved by the at least two host computers is maximized; and
controlling the at least two host computers to run the at least one virtual operative system instance as defined in the calculated arrangement.

Optionally, for each host computer, the controller computer is configured with a target minimum heat rate to be achieved by the host computer, and the step of calculating an arrangement comprises the step of:
calculating an arrangement of the at least one virtual operative system instance over the at least two host computers so that an amount of host computers achieving the respective target minimum heat rate is maximized.

Optionally, the step of estimating a heat rate comprises estimating the heat rate based on any of:
previous data about a heat rate that resulted from running the virtual operative system instance as a guest of a host computer;
real-time data about a heat rate that is resulting from running the virtual operative system instance as a guest of a host computer;
data generated by a mathematical model of a heat rate that results from running the virtual operative system instance as a guest of a host computer; and/or
data generated by a computer implemented simulation of a heat rate that results from running the virtual operative system instance as a guest of a host computer.

Optionally, the step of controlling the at least two host computers to run the at least one virtual operative system instance comprises the step of migrating a virtual operative system instance from one host computer to a different host computer.

Optionally, the controller computer is further configured to carry out any of the steps of:
shutting down a host computer that has not been controlled to run at least one virtual operative system instance; or
controlling a host computer that has not been controlled to run at least one virtual operative system instance so that the host computer runs in a mode for saving energy.

Optionally, the at least one virtual operative system instance comprises any of: a virtual machine instance; and/or a container instance.

According to a fourth aspect of the invention, there is provided a method of harnessing heat generated from running at least one virtual operative system instance, the method comprising the steps of:
providing at least two host computers for running the at least one virtual operative system instance, the at least two host computers being networked;
providing a subsystem for harnessing heat generated by the at least two host computers;
providing a controller computer for controlling the at least two host computers;
for each virtual operative system instance, estimating, by the controller computer, a heat rate that will result from running the instance as a guest of a host computer;
calculating, by the controller computer, an arrangement of the at least one virtual operative system instance over the at least two host computers so that a heat rate achieved by the at least two host computers is maximized; and
controlling, by the controller computer, the at least two host computers to run the at least one virtual operative system instance as defined in the calculated arrangement.

Optionally, the method comprises the step of:
for each host computer, configuring the controller computer with a target minimum heat rate to be achieved by the host computer, and
   wherein the step of calculating an arrangement comprises the step of:
calculating an arrangement of the at least one virtual operative system instance over the at least two host computers so that an amount of host computers achieving the respective target minimum heat rate is maximized.

Optionally, the step of estimating a heat rate comprises estimating the heat rate based on any of:
previous data about a heat rate that resulted from running the virtual operative system instance as a guest of the host computer;
real-time data about a heat rate that is resulting from running the virtual operative system instance as a guest of a host computer;
data generated by a mathematical model of a heat rate that results from running the virtual operative system instance as a guest of a host computer; and/or
data generated by a computer implemented simulation of a heat rate that results from running the virtual operative system instance as a guest of a host computer.

Optionally, the step of controlling the at least two host computers to run the at least one virtual operative system instance comprises the step of migrating a virtual operative system instance from one host computer to a different host computer.

Optionally, the method further comprises the steps of:
shutting down, by the controller computer, a host computer that has not been controlled to run at least one virtual operative system instance; or
controlling, by the controller computer, a host computer that has not been controlled to run at least one virtual operative system instance so that the host computer runs in a mode for saving energy.

Optionally, the at least one virtual operative system instance comprises any of: a virtual machine instance; and/or a container instance.

Thus, a system according to the first aspect of the invention includes the configuration of one or more of the at least two host computers to operate as a controller of the at least two host computers, whereas a system according to the third aspect of the invention includes a controller computer for controlling the at least two host computers. Similarly, a method according to the second aspect of the invention comprises the step of configuring one or more of the at least two host computers to operate as a controller of the at least two host computers, whereas a method according to the fourth aspect of the invention includes the step of providing a controller computer for controlling the at least two host computers.

### BRIEF DESCRIPTION OF THE DRAWINGS

In the drawings:

FIG. 1 shows schematic view of a system embodiment including four host computers, the four host computers running four virtual operative system instances;

FIG. 2 shows a schematic view of a one graph illustrating the distribution of computational load over four host computers being controlled to run virtual operative system instances as defined in one arrangement;

FIG. 3 shows a schematic view of another graph illustrating the distribution of computational load over four host computers being controlled to run virtual operative system instances as defined in another arrangement.

### DETAILED DESCRIPTION OF THE DRAWINGS

In the figures, same or corresponding elements are indicated by same reference numerals. For clarity reasons, some elements may in some of the figures be without reference numerals. A person skilled in the art will understand that the figures are just principal drawings. The relative proportions of individual elements may also be distorted.

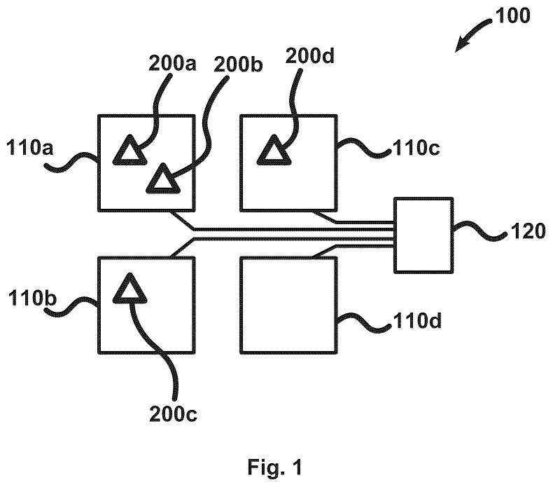

Turning now to FIG. 1, it shows a system embodiment 100 including four host computers 110a-110d for running four virtual operative system instances 200a-200d. The system 100 also includes a subsystem 120 for harnessing heat generated by the four host computers 110a-110d. It will be understood by the skilled person that the system 100 shown in FIG. 1 is illustrated in a simplified manner for the purpose of illustrating an embodiment of the invention. In other embodiments, the number, structure, form and/or organization of the at least two host computers and the heat harnessing subsystem may vary substantially and within what is known in the data center practice.

The host computers 110a-110d may be embodied in a manner known from the data center practice. For example, a data center may be provided in which a number of host computers is installed in various racks and with connection to known systems available in a typical data center, such as a power system, a network, an air-cooling system, among others. The host computers may be configured to operate software suitable for running virtual operative system instances, such as a hypervisor software (e.g. KVM) or a container engine software (e.g. Kubernetes).

The subsystem 120 for harnessing heat from the host computers 110a-110d may be provided in many known manners. For example, a known subsystem is based on a direct contact evaporative cooling system using a two-phase coolant (e.g. 3M™ Novec™ 7000 Engineered Fluid), the coolant having a pre-defined boiling temperature. The harnessing of heat is achieved by transmitting the coolant, in liquid phase, onto direct contact with one or more chips of a host computer 110a-110d. When that contact happens and the chip generates sufficient heat to cause the coolant to boil, the coolant evaporates and flows, in gaseous form, towards the subsystem 120. At that stage, the gaseous, hot coolant is used as a source of heat to be harnessed. The heat is harnessed and transmitted to an external facility for reuse. The harnessing of the heat from the coolant lowers the temperature of the coolant, which in turn causes the gaseous coolant to change back to the liquid phase. Harnessing heat from the hot, gaseous coolant may be achieved in many known ways, for example by a heat exchanger device in which the heat from the coolant is transferred to a separate circuit including a fluid (e.g. water) for transmitting the harnessed heat to an external facility. It will be understood that other subsystems 120 for harnessing heat are known and may be used for harnessing heat from one or more host computers.

In the system 100, the host computer 110a shown at the top left corner of FIG. 1 is additionally configured to operate as a controller for controlling the running of the four virtual operative system instances 200a-200d over the four host computers 110a-110d. It will be understood that the controller may be implemented in other known ways, including having the controller be executed in a cooperative or decentralized manner by two or more host computers, among other known approaches. It will also be understood that a host computer 110a-110d is configurable to both operate as the controller and run one or more virtual operative system instances. Moreover, it will be appreciated that in other implementations the system 100 may include a controller computer (not shown) for controlling the host computers 110a-110d, instead of having one or more of the host computers 110a-110d configured to operate as a controller.

In the embodiment shown in FIG. 1, the controller has controlled the four host computers 110a-110d to run the four virtual operative system instances 200a-200d as shown: the host computer 110a on the top-left corner is controlled to run two of the instances 200a,200b; the host computer 110b on the lower-left corner is controlled to run one instance 200c; and the host computer 110c on the top-right corner is controlled to run one instance 200d. This arrangement of the four virtual operative system instances 200a-200d over the four host computers 110a-110d was calculated so that a heat rate achieved by the four host computers 110a-110d is maximized. When calculating the arrangement, the controller carried out the step of estimating, for each virtual operative system instance 200a-200d, a heat rate that will result from running the instance as a guest of a host computer 110a-110d. This estimation of a heat rate may be implemented in many known ways. For example, the estimation may involve estimating the percentage of a period of time during which a temperature of a chip (e.g. CPU) in a host computer will be above a certain minimum temperature. Or, for example, the estimation may be implemented by estimating a heat rate in kWh. It will be understood that other known ways of estimating a heat rate may be used.

In some embodiments, the heat rate estimation is based on any of:
previous data about a heat rate that resulted from running the virtual operative system instance as a guest of a host computer;
real-time data about a heat rate that is resulting from running the virtual operative system instance as a guest of a host computer;
data generated by a mathematical model of a heat rate that results from running the virtual operative system instance as a guest of a host computer; and/or
data generated by a computer implemented simulation of a heat rate that results from running the virtual operative system instance as a guest of a host computer.

These data options may be chosen exclusively or non-exclusively combined in many ways.

Moreover, these data options may be combined with other known data options.

After the estimating step, the controller carries out a step of calculating the arrangement. The skilled person will know many search algorithms for efficiently finding an arrangement in which the heat rate achieved by the four host computers 110a-110d is maximized. Also, it will be appreciated that the skilled person will know how a plurality of heat rate estimates may be accumulated to represent a plurality of respective instances running as guests of the same host computer.

For example, in FIG. 1, the host computers 110b, 110c on the lower-left corner and the top-right corner have been controlled to run only one virtual operative system instance 200c,200d each. This portion of the arrangement resulted from estimating that each of the instances 200c,200d will cause a host computer to generate a heat rate sufficiently high to justify having only one instance running in each of the two host computers 110b,110c.

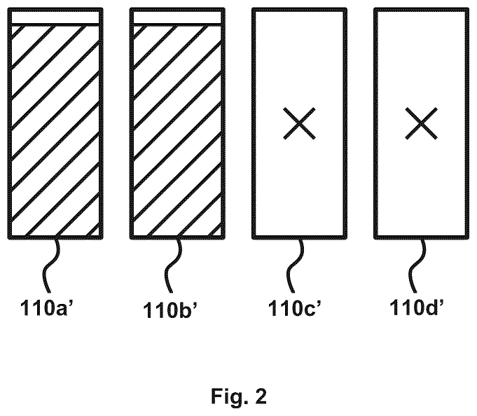

FIG. 2 shows, for a system embodiment, a graph illustrating the distribution of computational loads 110a′-110d′ over four host computers being controlled to run virtual operative system instances as calculated in one arrangement. The two host computers related to the computational loads 110a′,110b′ shown on the left-hand side of FIG. 2 have been assigned with all the instances to be run, whereas the two host computers related to the computational loads 110c′,110d′ shown on the right-hand side of FIG. 2 have not been assigned to run any instances. Also, the later host computers, i.e. related to the computational loads 110c′,110d′ on the right-hand side, have been shut down in order to reduce the power consumption. Thus, the rate of generated heat by the four host computers is maximized.

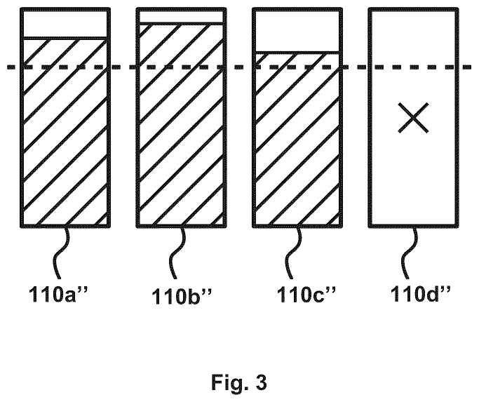

FIG. 3 shows, for a system embodiment, another graph illustrating the distribution of computational loads 110a″-110d″ over four host computers being controlled to run virtual operative system instances as calculated in another arrangement.

In FIG. 3, the controller of the system embodiment is, for each of the four host computers, configured with a target minimum heat rate to be achieved by the host computer. These four target minimum heat rate configurations are shown in FIG. 3 in the form of a dashed horizontal line intersecting the computational loads 110a″-110d″, thus representing that, in this particular embodiment, the controller is configured with the same target minimum heat rate for each of the four host computers. It will be understood that different target minimum heat rates may be configured for each host computer, and this configuration may take into account various parameters related to the heat generating capability of the host computer.

When calculating an arrangement of the at least one virtual operative system instance over the four host computers, the controller is configured to maximize an amount of host computers achieving the respective target minimum heat rate. As shown in FIG. 3, all the host computers running instances are achieving computational loads 110a″-110c″ above the target minimum heat rates, even though a few of them may still have capacity to run further instances.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. Use of the verb “comprise” and its conjugations does not exclude the presence of elements or steps other than those stated in a claim. The article “a” or “an” preceding an element does not exclude the presence of a plurality of such elements.

The mere fact that certain measures are recited in mutually different dependent claims does not indicate that a combination of these measures cannot be used to advantage.

The invention may be implemented by means of hardware comprising several distinct elements, and by means of a suitably programmed computer. In the system claim listing several means, several of these means may be embodied by one and the same item of hardware.

1. A system for harnessing heat generated from running at least one virtual operative system instance, the system comprising:
at least two host computers for running the at least one virtual operative system instance, the at least two host computers being networked; and
a subsystem for harnessing heat generated by the at least two host computers,
wherein one or more of the at least two host computers is configured to operate as a controller of the at least two host computers, and
wherein the controller is configured to carry out the steps of:
for each virtual operative system instance, estimating a heat rate that will result from running the instance as a guest of a host computer;
calculating an arrangement of the at least one virtual operative system instance over the at least two host computers so that a heat rate achieved by the at least two host computers is maximized; and
controlling the at least two host computers to run the at least one virtual operative system instance as defined in the calculated arrangement.

2. The system according to claim 1, wherein, for each host computer, the controller is configured with a target minimum heat rate to be achieved by the host computer, and
wherein the step of calculating an arrangement comprises the step of:
calculating an arrangement of the at least one virtual operative system instance over the at least two host computers so that an amount of host computers achieving the respective target minimum heat rate is maximized.

3. The system according to claim 1, wherein the step of estimating a heat rate comprises estimating the heat rate based on any of:
previous data about a heat rate that resulted from running the virtual operative system instance as a guest of a host computer;
real-time data about a heat rate that is resulting from running the virtual operative system instance as a guest of a host computer;
data generated by a mathematical model of a heat rate that results from running the virtual operative system instance as a guest of a host computer; and/or
data generated by a computer implemented simulation of a heat rate that results from running the virtual operative system instance as a guest of a host computer.

4. The system according to claim 1, wherein the step of controlling the at least two host computers to run the at least one virtual operative system instance comprises the step of migrating a virtual operative system instance from one host computer to a different host computer.

5. The system according to claim 1, wherein the controller is further configured to carry out any of the steps of:
shutting down a host computer that has not been controlled to run at least one virtual operative system instance; or
controlling a host computer that has not been controlled to run at least one virtual operative system instance so that the host computer runs in a mode for saving energy.

6. The system according to claim 1, wherein the at least one virtual operative system instance comprises any of: a virtual machine instance; and/or a container instance.

7. A method of harnessing heat generated from running at least one virtual operative system instance, wherein the method comprises the steps of:
providing at least two host computers for running the at least one virtual operative system instance, the at least two host computers being networked;
providing a subsystem for harnessing heat generated by the at least two host computers;
configuring one or more of the at least two host computers to operate as a controller of the at least two host computers;
for each virtual operative system instance, estimating a heat rate that will result from running the instance as a guest of a host computer;
calculating an arrangement of the at least one virtual operative system instance over the at least two host computers so that a heat rate achieved by the at least two host computers is maximized; and
controlling the at least two host computers to run the at least one virtual operative system instance as defined in the calculated arrangement.

8. The method according to claim 7, wherein the method comprises the step of:
for each host computer, configuring the controller with a target minimum heat rate to be achieved by the host computer, and
wherein the step of calculating an arrangement comprises the step of:
calculating an arrangement of the at least one virtual operative system instance over the at least two host computers so that an amount of host computers achieving the respective target minimum heat rate is maximized.

9. The method according to claim 7, wherein the step of estimating a heat rate comprises estimating the heat rate based on any of:
previous data about a heat rate that resulted from running the virtual operative system instance as a guest of the host computer;
real-time data about a heat rate that is resulting from running the virtual operative system instance as a guest of a host computer;
data generated by a mathematical model of a heat rate that results from running the virtual operative system instance as a guest of a host computer; and/or
data generated by a computer implemented simulation of a heat rate that results from running the virtual operative system instance as a guest of a host computer.

10. The method according to claim 7, wherein the step of controlling the at least two host computers to run the at least one virtual operative system instance comprises the step of migrating a virtual operative system instance from one host computer to a different host computer.

11. The method according to claim 7, wherein the controller is further configured to carry out any of the steps of:
shutting down a host computer that has not been controlled to run at least one virtual operative system instance; or
controlling a host computer that has not been controlled to run at least one virtual operative system instance so that the host computer runs in a mode for saving energy.

12. The method according to claim 7, wherein the at least one virtual operative system instance comprises any of: a virtual machine instance; and/or a container instance.

13. A system for harnessing heat generated from running at least one virtual operative system instance, wherein the system comprises:
at least two host computers for running the at least one virtual operative system instance, the at least two host computers being networked;
a subsystem for harnessing heat generated by the at least two host computers; and
a controller computer for controlling the at least two host computers, and wherein the controller computer is configured to carry out the steps of:
for each virtual operative system instance, estimating a heat rate that will result from running the instance as a guest of a host computer;
calculating an arrangement of the at least one virtual operative system instance over the at least two host computers so that a heat rate achieved by the at least two host computers is maximized; and
controlling the at least two host computers to run the at least one virtual operative system instance as defined in the calculated arrangement.

14. The system according to claim 13, wherein, for each host computer, the controller computer is configured with a target minimum heat rate to be achieved by the host computer, and wherein the step of calculating an arrangement comprises the step of:
calculating an arrangement of the at least one virtual operative system instance over the at least two host computers so that an amount of host computers achieving the respective target minimum heat rate is maximized.

15. The system according to claim 13, wherein the step of estimating a heat rate comprises estimating the heat rate based on any of:
previous data about a heat rate that resulted from running the virtual operative system instance as a guest of a host computer;
real-time data about a heat rate that is resulting from running the virtual operative system instance as a guest of a host computer;
data generated by a mathematical model of a heat rate that results from running the virtual operative system instance as a guest of a host computer; and/or
data generated by a computer implemented simulation of a heat rate that results from running the virtual operative system instance as a guest of a host computer.

16. The system according to claim 13, wherein the step of controlling the at least two host computers to run the at least one virtual operative system instance comprises the step of migrating a virtual operative system instance from one host computer to a different host computer.

17. The system according to claim 13, wherein the controller computer is further configured to carry out any of the steps of:
shutting down a host computer that has not been controlled to run at least one virtual operative system instance; or
controlling a host computer that has not been controlled to run at least one virtual operative system instance so that the host computer runs in a mode for saving energy.

18. The system according to claim 13, wherein the at least one virtual operative system instance comprises any of: a virtual machine instance; and/or a container instance.

19. A method of harnessing heat generated from running at least one virtual operative system instance,
wherein the method comprises the steps of:
providing at least two host computers for running the at least one virtual operative system instance, the at least two host computers being networked;
providing a subsystem for harnessing heat generated by the at least two host computers;
providing a controller computer for controlling the at least two host computers;
for each virtual operative system instance, estimating, by the controller computer, a heat rate that will result from running the instance as a guest of a host computer;
calculating, by the controller computer, an arrangement of the at least one virtual operative system instance over the at least two host computers so that a heat rate achieved by the at least two host computers is maximized; and
controlling, by the controller computer, the at least two host computers to run the at least one virtual operative system instance as defined in the calculated arrangement.

20. The method according to claim 19, wherein the method comprises the step of:
for each host computer, configuring the controller computer with a target minimum heat rate to be achieved by the host computer, and
wherein the step of calculating an arrangement comprises the step of:
calculating an arrangement of the at least one virtual operative system instance over the at least two host computers so that an amount of host computers achieving the respective target minimum heat rate is maximized.

21. The method according to claim 19, wherein the step of estimating a heat rate comprises estimating the heat rate based on any of:
previous data about a heat rate that resulted from running the virtual operative system instance as a guest of the host computer;
real-time data about a heat rate that is resulting from running the virtual operative system instance as a guest of a host computer;
data generated by a mathematical model of a heat rate that results from running the virtual operative system instance as a guest of a host computer; and/or
data generated by a computer implemented simulation of a heat rate that results from running the virtual operative system instance as a guest of a host computer.

22. The method according to claim 19, wherein the step of controlling the at least two host computers to run the at least one virtual operative system instance comprises the step of migrating a virtual operative system instance from one host computer to a different host computer.

23. The method according to claim 19, wherein the method further comprises the steps of:
shutting down, by the controller computer, a host computer that has not been controlled to run at least one virtual operative system instance; or
controlling, by the controller computer, a host computer that has not been controlled to run at least one virtual operative system instance so that the host computer runs in a mode for saving energy.

24. The method according to claim 19, wherein the at least one virtual operative system instance comprises any of: a virtual machine instance; and/or a container instance.
